(19) United States
(12) Patent Application Publication
(10) Pub. No.: US 2019/0116663 A1
(43) Pub. Date: Apr. 18, 2019

(54) Graphene-Graphane Printed Wiring Board

(71) Applicant: Lockheed Martin Corporation, Bethesda, MD (US)

(72) Inventor: David G. Findley, Fort Worth, TX (US)

(21) Appl. No.: 15/786,018

(22) Filed: Oct. 17, 2017

(51) Int. Cl. H05K 1/02; B32B 5/16; B32B 5/20; H05K 1/11; H05K 3/46; C09C 1/46

(52) U.S. Cl. CPC H05K 1/0271; B32B 5/16; B32B 5/20; C09C 1/46; H05K 1/0298; H05K 1/115; H05K 3/4608; H05K 1/0207

(57) ABSTRACT

A printed wiring board includes a first layer comprising a first plurality of conductive graphene traces and insulating graphane arranged to separate the first plurality of conductive graphene traces. The printed wiring board also includes a second layer and a third layer. The second layer includes an insulating layer. The third layer includes a second plurality of conductive graphene traces and insulating graphane arranged to separate the second plurality of conductive graphene traces. The second layer is disposed between the first layer and the third layer.

### TECHNICAL FIELD OF THE INVENTION

This invention relates generally to printed wiring boards (PWBs) constructed of graphene and graphane.

### BACKGROUND

Graphene is an allotrope of carbon demonstrating a “2-dimensional” structure with unique conductive properties. Printed wiring boards (PWBs), or circuit boards, are commonly used to connect electronic devices such as computer chips. PWBs are typically composed of layers of polymer and layers of metal, such as copper. Printed wiring boards are typically heavy, due to the presence of copper metal. PWBs also often demonstrate poor thermal conductivity due to the polymer components of the boards.

### SUMMARY

According to some embodiments, a printed wiring board includes a first layer comprising a first plurality of conductive graphene traces and insulating graphane arranged to separate the first plurality of conductive graphene traces. The printed wiring board also includes a second layer and a third layer. The second layer includes an insulating layer. The third layer includes a second plurality of conductive graphene traces and insulating graphane arranged to separate the second plurality of conductive graphene traces. The second layer is disposed between the first layer and the third layer.

According to some embodiments, a method for creating a printed wiring board includes coating a sheet of graphene with a polymer and producing a pattern in the polymer. The method further includes removing a portion of the patterned polymer to expose a plurality of areas of the sheet of graphene. The method also includes converting the exposed plurality of areas of the sheet of graphene to graphane to produce a graphene-graphane sheet having a plurality of graphene areas and a plurality of graphane areas, and removing the remaining polymer.

Technical advantages of certain embodiments may include using a single layer of graphene to form a printed wiring board. A printed wiring board including graphene and graphane may be lighter than a printed wiring board including metals. In certain embodiments, a printed wiring board including graphene and graphane may have greater thermal conductivity than a printed wiring board including conventional polymers. Additionally, in some embodiments, a printed wiring board including graphene and graphane may have greater flexibility than a printed wiring board including conventional polymers.

### BRIEF DESCRIPTION OF THE DRAWINGS

To provide a more complete understanding of the present invention and the features and advantages thereof, reference is made to the following description taken in conjunction with the accompanying drawings, in which:

FIG. 1 illustrates the molecular structure of graphene;

FIG. 2 illustrates the molecular structure of graphane;

FIG. 3 illustrates a single layer of a graphene-graphane printed wiring board, according to certain embodiments;

FIG. 4 illustrates a method of producing a graphene-graphane printed wiring board, according to certain embodiments;

FIG. 5 illustrates a graphene-graphane printed wiring board, according to certain embodiments;

FIG. 6 illustrates a method of producing a graphene-graphane printed wiring board without metal vias, according to certain embodiments; and

FIG. 7 illustrates a graphene-graphane printed wiring board, according to certain embodiments.

### DETAILED DESCRIPTION OF THE DRAWINGS

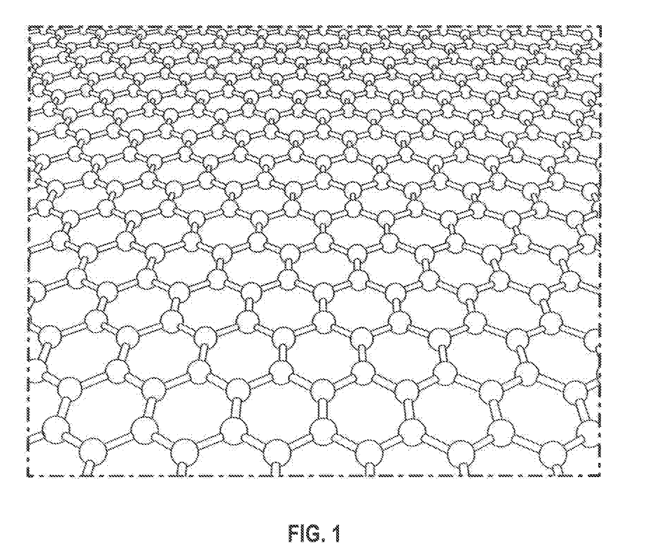

Embodiments of the present invention and its advantages are best understood by referring to FIGS. 1 through 7 of the drawings, like numerals being used for like and corresponding parts of the various drawings.

FIG. 1 illustrates the molecular structure of graphene. Graphene is a form of the element carbon that has many unique properties. Graphene is commonly referred to as “two-dimensional” (2-D) form of carbon, because the carbon atoms of graphene are arranged in a flat, planar structure that is a single atom thick. The carbon atoms of graphene are bonded in the sp orbital hybridization. As a result of its structure, graphene has several unique properties. It demonstrates high electron mobility, and has high electrical conductivity in the direction along the plane. Graphene is also highly thermally conductive. Additionally, graphene is one of the strongest materials known, having a high tensile strength and a low weight. Graphene may be produced in a variety of ways, some of which are described in the present disclosure.

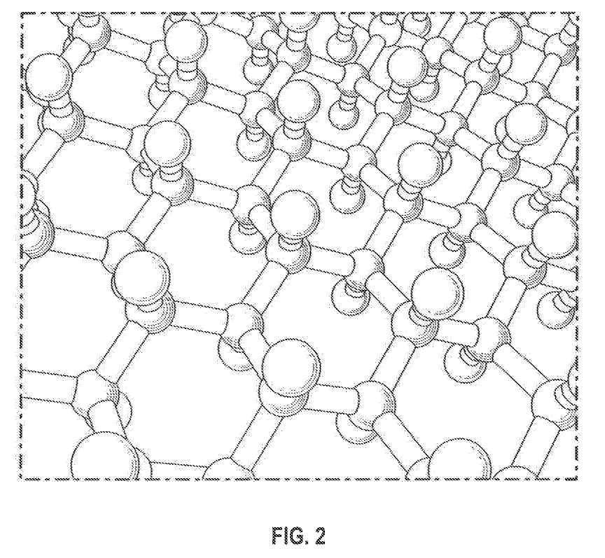

FIG. 2 illustrates the molecular structure of graphane. Graphane is a 2-D polymer of carbon and hydrogen. Graphane can be regarded as a hydrogenated form of graphene, with each carbon atom bonded to one hydrogen atom and three other carbon atoms. Unlike graphene, the carbon atoms of graphane are bonded in an sp³ configuration. Unlike graphene, graphane is an electrical insulator. Graphane can be produced by hydrogenation of graphene, for which there exists a variety of methods. One method of converting graphene to graphane is by atomic hydrogen bombardment in an electrolytic bath. Another method of converting graphene to graphane is by atomic hydrogen plasma bombardment.

Halo-graphenes have a similar structure to graphane, with one halogen atom bonded to each carbon atom in the place of the hydrogen atoms of graphane. Like graphane, the carbon atoms of halo-graphenes are bonded in the sp³ configuration. Two examples of halo-graphenes include fluorographene and chlorographene. Fluorographene has a structure in which a fluorine atom is bonded to each carbon atom, in a similar manner to the hydrogen atoms of graphane. Chlorographene has a structure in which a chlorine atom is bonded to each carbon atom, in a similar manner to the hydrogen atoms of graphane.

The teachings of the disclosure recognize that selectively converting portions of a graphene layer to graphane may provide a structure that can be used as a printed wiring board (PWB) or as portion of a PWB. In particular, a PWB may be manufactured with non-electrically conducting graphane areas separating conducting graphene areas. The graphene areas may be arranged in such a way as to act as electrically conductive traces or wires.

The teachings of the disclosure further recognize that multiple layers comprising graphene and graphane may be arranged to perform the function of a PWB. A graphene-graphane PWB may have numerous technical advantages due to the high thermal conductivity of graphene and graphane and the low density of graphene and graphane compared to metals commonly used in PWBs. Additionally, the broad optical and infrared transparency of carbon allotropes may be used to facilitate optical and infrared data paths within the PWB (i.e. a waveguide).

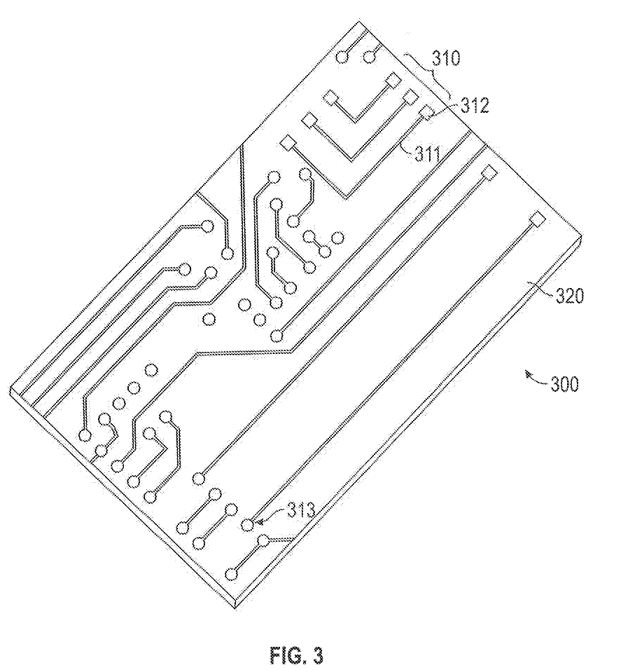

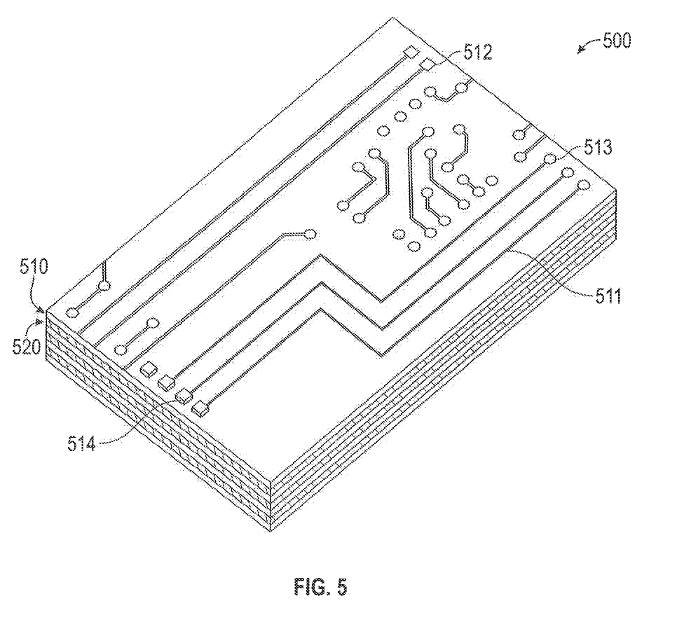

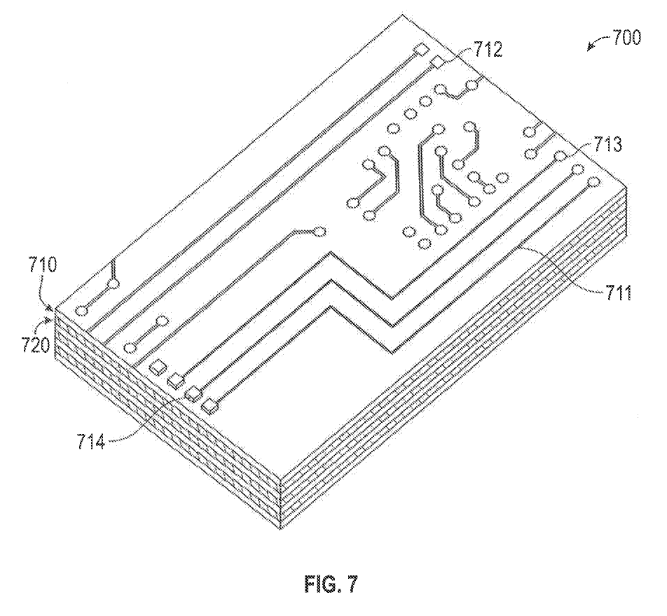

FIG. 3 illustrates an example embodiment of a graphene graphane layer 300 of a graphene-graphane printed wiring board, such as graphene-graphane printed wiring board 500 illustrated in FIG. 5 or graphene-graphane printed wiring board 700 illustrated in FIG. 7. Graphene-graphane layer 300 may include areas of graphene 310 and graphane 320. Graphene 310 may be electrically conductive and graphane 320 may provide electrical insulation between areas of graphene 310. Areas of graphene 310 may include electrically conductive traces 311, attachment pads 312, and locations for vias 313. In certain embodiments, graphene-graphane layer 300 may include all, some, or none of these elements. In some embodiments, graphane 320 may be replaced with a halo-graphene. In particular embodiments, the halo-graphene may include fluorographene and chlorographene.

Graphene 310 may be arranged so as to accommodate transmission of electrical signals from one location of graphene-graphane layer 300 to another location of graphene-graphane layer 300. In some embodiments, attachment pads 312 may be plated with a thin film layer of conductive metal, including copper, silver, gold, aluminum, nickel, lead, tin, combinations or alloys thereof, or any other conductive metal. The thin film layer of conductive metal may provide electrical contact between conductive graphene 310 and an electrical component, such as electrical component 514 illustrated in FIG. 5 or electrical component 714 illustrated in FIG. 7, mounted on a graphene-graphane layer 300 of a graphene-graphane printed wiring board. In other embodiments, graphene-graphane layer 300 may not be plated with any metal. For example, if used as a graphene-graphane layer 710 of graphene-graphane printed wiring board 700 illustrated in FIG. 7, graphene-graphane-graphane layer 300 may have no metal plating in order to facilitate formation of Q-carbon vias.

Electrical component 514 or electrical component 714 may include any electrical component commonly attached to a printed wiring board, including, but not limited to, computer processors, computer memory, resistors, capacitors, inductors, batteries, power sources, and any other suitable electronic component. Locations for vias 313 may provide a location for electrically conductive traces 311 to be electrically connected to electrically conductive traces of other graphene-graphane layers in a graphene-graphane printed wiring board.

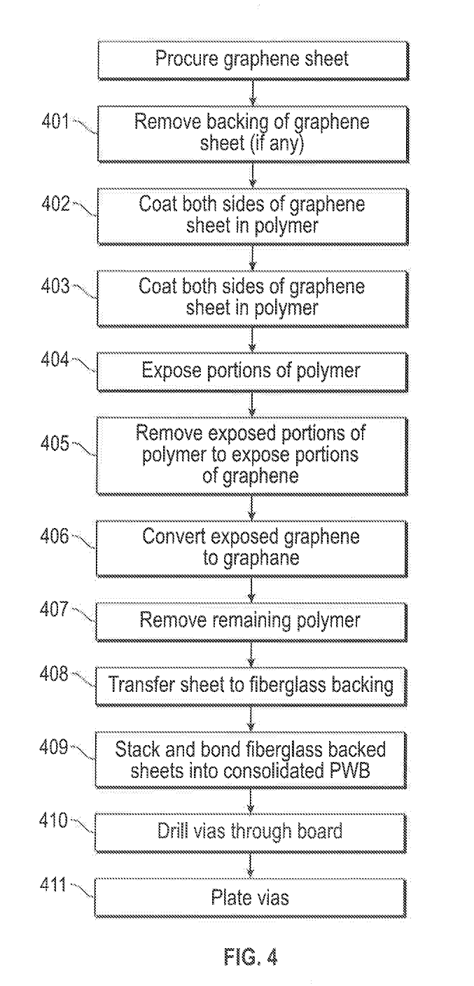

FIG. 4 illustrates an example method 400 of creating a graphene-graphane printed wiring board. Steps 401 through 407 describe a method for producing a graphene-graphane layer 300 as illustrated by FIG. 3. The method may begin with a single layer of graphene. In some embodiments, graphene may be obtained as a sheet comprising a layer of graphene and a backing material. In some embodiments, the backing material may be a polymer, such as poly(methyl methacrylate) (PMMA). In other embodiments, the backing material may be any acceptable surface upon which graphene can be deposited or grown.

At step 401, the backing material, if any, may be removed from the sheet of graphene. In other embodiments, the backing may not be removed and the process may proceed directly to step 402. In particular embodiments, the backing material may be removed by dissolving the backing layer in a solvent. Removing the backing material may result in a sheet of pure graphene.

At step 402, the front and back of the sheet of graphene produced in step 401 may be coated with a polymer. If method 400 proceeds directly to step 402, only one side of the graphene sheet may be coated in polymer, as the hacking may remain in place on the other side of the graphene sheet. In some embodiments, the polymer may be a photoresist polymer. In other embodiments, the graphene sheet may be coated with two layers of polymer. The first layer may be a conventional polymer such as PMMA that can be dissolved in a solvent. A second, photoresist polymer layer may be deposited onto the first layer of polymer. In embodiments in which the backing material is not removed from the graphene sheet, a first polymer may be deposited on the side of the graphene sheet opposite the backing material, and a photoresist polymer may be deposited upon the first polymer layer and the backing material. In some embodiments, the first polymer layer may be the same polymer as the backing material.

At step 403, portions of the photoresist polymer are treated to produce a pattern in the photoresist polymer. Patterning the polymer may cause chemical changes in the photoresist polymer that enable portions of the photoresist polymer to be selectively removed from the graphene sheet in step 404. Photolithographic techniques may be used to pattern the photoresist polymer. For example, the polymer may be exposed to electromagnetic radiation though the use of a patterned mask, causing the radiation to contact portions of the polymer but not others. In some embodiments, the electromagnetic radiation may be visible spectrum or ultraviolet light. In other embodiments, the electromagnetic radiation may be an electron beam. In some embodiments, each side of the graphene sheet may be exposed to the same pattern. In some embodiments, the patterns on each side of the graphene sheet may be aligned.

At step 404, portions of the photoresist polymer may be removed to expose portions of the graphene sheet. The polymer may be removed by a variety of techniques including, but not limited to, use of solvents to selectively dissolve portions of the photoresist polymer, use of thermal processes to selectively remove portions of the photoresist polymer, and the use of plasmas or ions to selectively remove portions of the photoresist polymer. In some embodiments, potions of the photoresist polymer that were exposed to electromagnetic radiation in step 403 may be removed. In some embodiments, portions of the photoresist polymer that were not exposed to electromagnetic radiation in step 403 may be removed. In embodiments having two polymer layers, and embodiments in which the backing material was left on the graphene layer, the photoresist polymer may be removed as described above and the first polymer layer may be removed by a solvent. In other embodiments, the photoresist polymer and the first polymer layer may be removed at the same time by any of the techniques described above.

At step 405, the graphene sheet is processed to convert the exposed graphene into graphane, resulting in a graphene-graphane-graphane sheet. Converting graphene into graphane may be accomplished by hydrogenating the exposed graphene. In some embodiments, electrolytic atomic hydrogen bombardment may be used to hydrogenate the exposed graphene. In other embodiments, converting graphene into graphane may be accomplished by contact with atomic hydrogen plasma. The polymer that was not removed in step 404 may prevent atomic hydrogen from contacting the underlying graphene, thereby preventing portions of the graphene from being converted into graphane. By selectively removing polymer to leave polymer in the shapes of graphene traces 311, attachment pads 312, and via locations 313 of FIG. 3, graphene may be left in the pattern of these features.

At step 406, the remaining polymer is removed from the graphene-graphane sheet. In some embodiments, the polymer may be removed by use of a solvent. After removal of the remaining polymer, a graphene-graphane sheet having patterned graphene features, such as those illustrated with respect to graphene-graphane layer 300 of FIG. 3, may result.

In an alternative embodiment, a graphene-graphane sheet may be produced by converting a bare graphene sheet to a graphane sheet in a manner similar to that described with respect to step 405. An electron beam may then be used to selectively dehydrogenate portions of the graphane sheet into graphene, thereby forming a graphene pattern in the graphane sheet. The graphene pattern formed by the electron beam may include features such as graphene traces 311, attachment pads 312, and via locations 313 as illustrated with respect to graphene-graphane sheet 300 of FIG. 3. Such a process may eliminate the need to use photoresist polymers to pattern the graphene sheet, but may be a slower method of producing a graphene pattern than the process described with respect to steps 402-406 because the electron beam may need to individually scan each graphene feature to be produced on the graphane sheet.

At step 407, conductive metal may be deposited onto portions of the graphene. In some embodiments, the conductive metal may be deposited by sputtering. In particular embodiments, the conductive metal may be copper. In some embodiments, the conductive metal may be deposited to have a thickness less than 10 nm. In certain embodiments, the conductive metal may be deposited at locations for vias in a printed wiring board. The conductive metal may be deposited on portions of the graphene traces such as attachment pads 312 and via locations 313 as illustrated in FIG. 3.

At step 408, the graphene-graphane sheet may be transferred to a structural sheet. The structural sheet may comprise a structural sheet or other polymer-composite sheet commonly used in the production of printed wiring boards. The graphene-graphane sheet may be adhered to the structural sheet by an adhesive. In some embodiments, the structural sheet may be pre-impregnated with an adhesive or resin to enable bonding with the graphene-graphane sheet. In some embodiments, step 408 may occur after step 406 and before step 407.

At step 409, the graphene-graphane-fiberglass sheets may be stacked with other graphene-graphane-fiberglass sheets in such a manner such that each graphene-graphane layer is separated by a structural layer. The structural layer may serve as an insulating layer between each graphene-graphane layer. As many graphene-graphane-fiberglass sheets as needed may be stacked to form a printed wiring board.

At step 410, vias may be drilled though the printed wiring board. In some embodiments, vias may be drilled at the locations of the conductive metal deposited in step 407. A via may provide a path from one of the conductive metal pads of one graphene-graphane layer in the printed wiring board to one of the conductive metal pads of one or more other graphene-graphane layers in the printed wiring board.

At step 411, the drilled vias may be plated with a conductive metal. The conductive metal may provide an electrical connection between graphene traces on different layers within the printed wiring board. In some embodiments, the conductive metal may be any acceptable conductive metal, including, but not limited to, copper, silver, gold, nickel, lead, aluminum, tin, and alloys of these metals. In particular embodiments, the conductive metal may be copper.

FIG. 5 illustrates a graphene-graphane printed wiring board 500, according to certain embodiments. The graphene-graphane printed wiring board 500 may have one or more graphene-graphane layers 510, and one or more structural layers 520. The graphene-graphane layers 510 may contain graphene traces 511, attachment pads 512, and through-vias 513. Vias 513 may electrically connect graphene traces 511 between different graphene-graphane layers 510. In some embodiments, vias 513 may be drilled through graphene-graphane printed wiring board 500 and plated with a conductive metal, as described in method 400.

Electrical components 514 may also be attached to graphene-graphane printed wiring board 500. In some embodiments, electrical components 514 may be attached to attachment pads 512. In other embodiments, electrical components 514 may be attached directly to graphene traces 511. Graphene traces 511 and vias 513 may electrically connect and conduct electrical signals between electrical components 514. In some embodiments, attachment pads 512 may be plated with a thin film layer of conductive metal, including copper, silver, gold, nickel, lead, aluminum, tin, combinations or alloys thereof, or any other conductive metal. The thin film layer of conductive metal may provide electrical contact between an electrical component 514 mounted on graphene-graphane printed wiring board 500 and conductive graphene traces 511 disposed throughout graphene-graphane printed wiring board 500. Electrical components 514 may include any electrical component commonly attached to a printed wiring board, including, but not limited to, computer processors, computer memory, resistors, capacitors, inductors, batteries, power sources, and any other suitable electronic component.

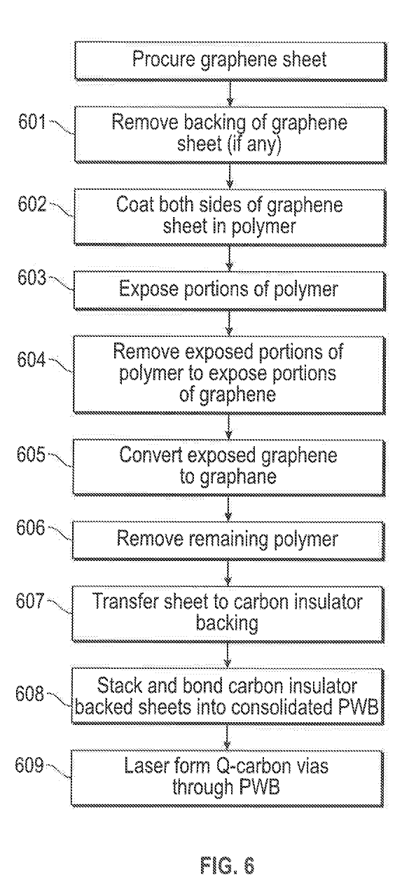

Graphene-graphane printed wiring board 500 may also be amenable to electronic components constructed of 2-D crystal materials, such as electronic components 514. For example, a processor constructed of 2-D crystal materials may be bonded directly to graphene traces 511 by laser heating and melting of the point of contact between graphene traces 511 and a 2-D crystal processor to form a conductive Q-carbon bond between one or more graphene traces 511 and the 2-D crystal material processor. The process for producing conductive Q-carbon is described in greater detail with respect to method 600 illustrated by FIG. 6.

In certain embodiments, graphene-graphane printed wiring board 500 may be coated in a polymer compound.

Such a polymer coating may protect graphene-graphane printed wiring board 500 from corrosion, heat, or mechanical wear and tear.

FIG. 6 illustrates a method 600 for producing a multilayer graphene-graphane printed wiring board without metal vias. Method 600 may begin with a single layer of graphene. In some embodiments, graphene may be obtained as a sheet comprising a layer of graphene and a backing material. In some embodiments, the backing material may be a polymer, such as PMMA. In other embodiments, the backing material may be any acceptable surface upon which graphene can be deposited or grown.

At step 601, the backing material, if any, may be removed from the sheet of graphene. In other embodiments, the backing may not be removed and the process may proceed to step 602. In particular embodiments, the backing material may be removed by dissolving the backing layer in a solvent. Removing the backing material may leave a sheet of pure graphene.

At step 602, the front and back of the sheet of graphene produced in step 601 may be coated with a polymer. If method 600 proceeds directly to step 602, only one side of the graphene sheet may be coated in polymer, as the backing may remain in place on the other side of the graphene sheet. In some embodiments, the polymer may be a photoresist polymer. In other embodiments, the graphene sheet may be coated with two layers of polymer. The first layer may be a conventional polymer, such as PMMA, that can be dissolved in a solvent. A second, photoresist polymer layer may be deposited onto the first layer of polymer. In embodiments in which the backing material is not removed from the graphene sheet, a first polymer may be deposited on the side of the graphene sheet opposite the backing material, and a photoresist polymer may be deposited upon the first polymer layer and the backing material. In some embodiments, the first polymer layer may be the same polymer as the backing material.

At step 603, portions of the photoresist polymer are treated to produce a pattern in the photoresist polymer. Patterning the polymer may cause chemical changes in the photoresist polymer that enable portions of the photoresist polymer to be selectively removed from the graphene sheet in step 604. Photolithographic techniques may be used the pattern the photoresist polymer. For example, the polymer may be exposed to electromagnetic radiation though the use of a patterned mask, causing the radiation to contact portions of the polymer but not others. In some embodiments, the electromagnetic radiation may be visible spectrum or ultraviolet light. In other embodiments, the electromagnetic radiation may be an electron beam. In some embodiments, each side of the graphene sheet may be exposed to the same pattern. In some embodiments, the pattern on each side of the graphene sheet may be aligned.

At step 604, portions of the photoresist polymer may be removed to expose portions of the graphene sheet. The polymer may be removed by a variety of techniques including, but not limited to, use of solvents to selectively dissolve portions of the photoresist polymer, use of thermal processes to selectively remove portions of the photoresist polymer, and the use of plasmas or ions to selectively remove portions of the photoresist polymer. In some embodiments, potions of the photoresist polymer that were exposed to electromagnetic radiation in step 603 may be removed. In some embodiments, portions of the photoresist polymer that were not exposed to electromagnetic radiation in step 603 may be removed. In embodiments having two polymer layers, and embodiments in which the backing material was left on the graphene layer, the photoresist polymer may be removed as described above and the first polymer layer may be removed by a solvent. In other embodiments the photoresist polymer and the first polymer layer may be removed at the same time by any of the techniques described above.

At step 605, the graphene sheet is processed to convert the exposed graphene into graphane, resulting in a graphene-graphane sheet. Converting graphene into graphane may be accomplished by hydrogenating the exposed graphene. In some embodiments, electrolytic atomic hydrogen bombardment may be used to hydrogenate the exposed graphene. In other embodiments, converting graphene into graphane may be accomplished by contact with atomic hydrogen plasma. The polymer that was not removed in step 604 may prevent atomic hydrogen from contacting the underlying graphene, thereby preventing portions of the graphene from being converted into graphane. By selectively removing polymer to leave polymer in the shapes of graphene traces 311, attachment pads 312, and via locations 313 of FIG. 3, graphene may be left in the pattern of these features.

At step 606, the remaining polymer is removed from the graphene-graphane sheet. In some embodiments, the polymer may be removed by use of a solvent. After removal of the remaining polymer, a graphene-graphane sheet having patterned graphene features, such as those illustrated on graphene-graphane sheet 300 of FIG. 3, may result.

In an alternative embodiment, a graphene-graphane sheet may be produced by converting a bare graphene sheet to a graphane sheet in a manner similar to that described with respect to step 605. An electron beam may then be used to selectively dehydrogenate portions of the graphane sheet into graphene, thereby forming a graphene pattern in the graphane sheet. The graphene pattern formed by the electron beam may include features such as graphene traces 311, attachment pads 312, and via locations 313 as illustrated with respect to graphene-graphane sheet 300 of FIG. 3. Such a process may eliminate the need to use photoresist polymers to pattern the graphene sheet, but may be a slower method of producing a graphene pattern than the process described with respect to steps 602-606 because the electron beam may need to individually scan each graphene feature to be produced on the graphane sheet.

At step 607, the graphene-graphane sheet may be transferred to a carbon insulating sheet to form a sheet having a graphene-graphane layer and a carbon insulating layer. In some embodiments, the carbon insulating sheet may be a pure graphane sheet. A graphane sheet may be produced by hydrogenating a graphene sheet without any polymer coating as described above with respect to step 605. In other embodiments, the carbon insulating sheet may include a halo-graphene, such as chlorographene or fluorographene. In some embodiments, the graphene-graphane sheet may be adhered to the carbon insulating sheet by Van der Waals forces or an electro static interaction acting between the sheets. In other embodiments, the graphene-graphane sheet may be adhered to the carbon insulating sheet by layer of adhesive. In particular embodiments, the layer of adhesive may include primarily carbon and may be no more than ten nanometers thick.

At step 608, the sheet having a graphene-graphane layer and a carbon insulating layer may be stacked with other sheets having a graphene-graphane layer and a carbon insulating layer in such a manner that each graphene-graphane layer is separated by a carbon insulating layer. As many sheets having a graphene-graphane layer and a carbon insulating layer sheets as needed may be stacked to form a printed wiring board. In certain embodiments, vias may be formed through one or more stacked graphene-graphane layers and carbon insulating layers, according to the description provided at step 609, prior to stacking additional graphene-graphane layers and carbon insulating layers. In these embodiments, the laser used to form Q-carbon vias may melt through the entire stack of graphene-graphane layers and carbon insulating layers. Therefore, in these embodiments, it is necessary to form Q-carbon vias through a partial stack of graphene-graphane layers and carbon insulating layers prior to adding additional graphene-graphane layers and carbon insulating layers. In this manner, vias running partially through a printed wiring board may be formed as the printed wiring board is constructed by stacking additional graphene-graphane layers and carbon insulating layers.

At step 609, vias may be formed though the printed wiring board. In some embodiments, vias may be formed by using a laser to convert the graphene and graphane layers into conductive Q-carbon. Directing a momentary pulse of laser light at the printed wiring board may result in rapid localized heating and melting of carbon of the graphene and graphane layers. Following the laser pulse, the melted carbon areas may quickly cool, or quench. The high thermal conductivity of graphene and graphane may further effect rapid cooling of carbon melted by the laser pulse. A via may provide a path from one of the conductive graphene traces of one graphene-graphane layer in the printed wiring board to one or more other conductive graphene traces of one or more other graphene-graphane layers in the printed wiring board through one or more carbon insulating layers in the printed wiring board.

FIG. 7 illustrates a graphene-graphane printed wiring board 700, according to certain embodiments. The graphene-graphane printed wiring board 700 may have one or more graphene-graphane layers 710, and one or more carbon insulating layers 720. In some embodiments, carbon insulating layers 720 may comprise a layer of graphane. In other some embodiments, carbon insulating layers 720 may comprise halo-graphene compounds. In particular embodiments, carbon insulating layers 720 may comprise fluorographene or chlorographene. The graphene-graphane layers 710 may contain graphene traces 711, through-vias 712, and attachment pads 713.

Vias 712 may electrically connect graphene traces 711 between different graphene-graphane layers 710. In some embodiments, vias 712 may be a Q-carbon layer formed by a laser. Q-carbon is a conductive allotrope of carbon that has been formed from carbon irradiated my momentary pulses of UV light. The Q-carbon of the present disclosure may be formed from momentary pulses of laser light directed at the graphene-graphane printed wiring board 700. In some embodiments, Q-carbon vias 712 may be substantially hollow. In other embodiments, Q-carbon vias 712 may be solid. In certain embodiments, Q-carbon vias 712 may be substantially hollow cylinders. In other embodiments, Q-carbon vias 712 may be solid cylinders. In yet other embodiments, Q-carbon vias 712 may be solid toroids.

Producing Q-carbon vias 712 with a laser may create a via spanning the entire thickness of graphene-graphane printed wiring board 700. To create a printed wiring board with vias though a portion of the thickness of the printed wiring board, multiple partial graphene-graphane printed wiring boards may be stacked. A partial graphene-graphane printed wiring board may comprise one or more graphene-graphane layers 710, and one or more graphane insulating layers 720. Vias on each partial graphene-graphane printed wiring board may be in locations that do not align with other vias when the partial printed wiring boards are stacked, resulting in vias that run partially through the resulting composite graphene-graphane printed wiring board (i.e., bind or buried vias).

Electrical components 714 may also be attached to graphene-graphane printed wiring board 700. In some embodiments, electrical components 714 may be attached to attachment pads 712. In other embodiments, electrical components 714 may be attached directly to graphene traces 711. Graphene traces 711 and vias 712 may electrically connect and conduct electrical signals between electrical components 714.

In some embodiments, attachment pads 712 may be plated with a thin film layer of conductive metal, including copper, silver, gold, nickel, lead, aluminum, tin, combinations or alloys thereof, or any other conductive metal. The thin film layer of conductive metal may provide electrical contact between an electrical component 714 mounted on graphene-graphane printed wiring board 700 and conductive graphene traces 711 disposed throughout graphene-graphane printed wiring board 700. In such embodiments, only the outer graphene-graphane layers 710 of graphene-graphane printed wiring board 700 may be plated with a conductive metal to enable an electrical connection between electronic devices 714 and graphene traces 711. In such embodiments, graphene-graphane layers 710 interior to graphene-graphane printed wiring board 700 may not be plated with any metal to facilitate formation of Q-carbon vias throughout graphene-graphane printed wiring board 700.

In other embodiments, electrical component 714 may be bonded directly to graphene traces 711 by laser heating and melting of the point of contact between graphene traces 711 and electrical component 714 to form a conductive Q-carbon bond between one or more graphene traces 711 and electrical component 714.

Electrical components 714 may include any electrical component commonly attached to a printed wiring board, including, but not limited to, computer processors, computer memory, resistors, capacitors, inductors, batteries, power sources, and any other suitable electronic component.

Graphene-graphane printed wiring board 700 may comprise any number of graphene-graphane layers 710 and carbon insulating layers 720. In some embodiments, graphene-graphane printed wiring board 700 may comprise less than 1000 layers. In some embodiments, graphene-graphane printed wiring board 700 may comprise less than 100 layers. In some embodiments, graphene-graphane printed wiring board 700 may comprise less than 50 layers.

In certain embodiments, graphene-graphane printed wiring board 700 may be coated in a polymer compound. Such a polymer coating may protect graphene-graphane printed wiring board 700 from corrosion, heat, or mechanical wear and tear.

Graphene-graphane printed wiring board 700 may be conformably attached to a surface, in particular embodiments. For example, graphene-graphane printed wiring board 700 may be attached to the interior surface of the wing of an aircraft. The interior surface of the wing of an aircraft may have a curvature, and the graphene-graphane printed wiring board 700 may follow this curvature. In particular embodiments, the a graphene-graphane printed wiring board 700 attached to the interior surface of the wing of an aircraft may be immersed in fuel. The fuel may serve to conduct heat away from graphene-graphane printed wiring board 700, thereby cooling the printed wiring board. In such a design, external cooling apparatus such as heat sinks, cooling fluid, and cooling pumps may not be needed to cool graphene-graphane printed wiring board 700, thereby saving the weight of these components on the aircraft.

In a similar manner, graphene-graphane printed wiring board 700 may be affixed to any surface that could provide cooling to graphene-graphane printed wiring board 700. For example, graphene-graphane printed wiring board 700 may be affixed to a surface in contact with a high fluid or gas flow, or to an underwater surface.

Graphene-graphane printed wiring board 700 may also be amenable to electronic components constructed of 2-D crystal materials, such as electronic components 714. For example, a processor constructed of 2-D crystal materials may be bonded directly to graphene traces 711 by laser heating and melting of the point of contact between graphene traces 711 and a 2-D crystal processor to form a conductive Q-carbon bond between one or more graphene traces 711 and the 2-D crystal material processor.

Modifications, additions, or omissions may be made to the methods described herein without departing from the scope of the invention. For example, the steps may be combined, modified, or deleted where appropriate, and additional steps may be added. Additionally, the steps may be performed in any suitable order without departing from the scope of the present disclosure.

Although the present invention has been described with several embodiments, a myriad of changes, variations, alterations, transformations, and modifications may be suggested to one skilled in the art, and it is intended that the present invention encompass such changes, variations, alterations, transformations, and modifications as fall within the scope of the appended claims.

What is claimed is:

1. A printed wiring board (PWB) comprising:
a first layer comprising:
a first plurality of conductive graphene traces; and
insulating graphane arranged to separate the first plurality of conductive graphene traces;
a second layer comprising an insulating layer;
a third layer comprising:
a second plurality of conductive graphene traces; and
insulating graphane arranged to separate the second plurality of conductive graphene traces; and
wherein the second layer is disposed between the first layer and the third layer.

2. The PWB of claim 1, wherein the insulating layer comprises graphane.

3. A printed wiring board (PWB) comprising:
a first layer comprising:
a plurality of conductive graphene traces; and
insulating graphane arranged to separate the plurality of conductive graphene traces.

4. The PWB of claim 3, further comprising an electrical component coupled to at least one of the plurality of conductive graphene traces.

5. The PWB of claim 3, further comprising a second layer comprising:
a plurality of conductive graphene traces;
insulating graphane arranged to separate the plurality of conductive graphene traces of the second layer; and
wherein the first layer is separated from the second layer by an insulating layer.

6. The PWB of claim 5, wherein the insulating layer comprises a layer of graphane.

7. The PWB of claim 5, wherein at least one of the plurality of conductive graphene traces of the first layer is electrically connected to at least one of the plurality of conductive graphene traces of the second layer.

8. The PWB of claim 5, wherein at least one of the plurality of conductive graphene traces of the first layer is electrically connected to at least one of the plurality of conductive graphene traces of the second layer by a conductive metal via.

9. The PWB of claim 6, wherein at least one of the plurality of conductive graphene traces of the first layer is electrically connected to at least one of the plurality of conductive graphene traces of the second layer by a Q-carbon via.

10. The PWB of claim 3, wherein the insulating graphane comprises halo-graphene.

11. The PWB of claim 3, further comprising a 2-D crystalline electronic component coupled to at least one of the plurality of conductive graphene traces.

12. A method for creating a printed wiring board (PWB) comprising:
coating a first graphene sheet with a first polymer;
producing a first pattern in the first polymer;
removing a portion of the patterned first polymer to expose a plurality of areas of the first graphene sheet;
converting the exposed plurality of areas of the first graphene sheet to graphane to produce a first graphene-graphane sheet having a plurality of graphene areas and a plurality of graphane areas; and
removing the remaining first polymer.

13. The method of claim 12, further comprising:
coating a second graphene sheet with a second polymer;
producing a second pattern in the second polymer;
removing a portion of the patterned second polymer to expose a plurality of areas of the second graphene sheet;
converting the exposed plurality of areas of the second graphene sheet to graphane to produce a second graphene-graphane sheet having a plurality of graphene areas and a plurality of graphane areas;
removing the remaining second polymer; and
stacking the first graphene-graphane sheet on top of an insulating sheet and the second graphene-graphane sheet such that the insulating sheet is disposed between the first graphene-graphane sheet and the second graphene-graphane sheet.

14. The method of claim 12, wherein converting the exposed plurality of areas of the first graphene sheet to graphane comprises hydrogenating the exposed plurality of areas of the first graphene sheet.

15. The method of claim 13, further comprising drilling one or more vias between at least one of the plurality of graphene areas of the first graphene-graphane sheet and at least one of the plurality of graphene areas of the second graphene-graphane sheet.

16. The method of claim 12, further comprising exposing at least one of the plurality of graphene areas of the first graphene-graphane sheet to a laser to convert the at least one of the plurality of graphene areas of the first graphene-graphane sheet to Q-carbon.

17. The method of claim 12, wherein at least one of the exposed plurality of areas of the first graphene sheet is converted to halo-graphene by halogenation.

18. The method of claim 13, wherein the insulating sheet comprises graphane.

19. The method of claim 13, wherein hydrogenating the exposed plurality of areas of the first graphene sheet comprises utilizing atomic hydrogen bombardment on the exposed plurality of areas of the first graphene sheet.

20. The method of claim 12, further comprising coupling an electrical component to at least one of the plurality, of graphene areas of the first graphene-graphane sheet.
